(19) United States
(12) Patent Application Publication
(10) Pub. No.: US 2014/0292172 A1
(43) Pub. Date: Oct. 2, 2014

(54) IMAGE READING APPARATUS

(71) Applicant: SEIKO EPSON CORPORATION, Tokyo (JP)

(72) Inventors: Hidetaka KAWATA, Suwa-shi (JP); Yoshiyuki OKAZAWA, Shiojiri-shi (JP)

(73) Assignee: SEIKO EPSON CORPORATION, Tokyo (JP)

(21) Appl. No.: 14/223,152

(22) Filed: Mar. 24, 2014

(30) Foreign Application Priority Data
Mar. 28, 2013 (JP) 2013-069412

(51) Int. Cl. H04N 1/00; B65H 7/00; H05K 5/02

(52) U.S. Cl. CPC H04N 1/00557; H05K 5/0239; H05K 5/0226; B65H 7/00
USPC 312/326; 271/264

(57) ABSTRACT

An image reading apparatus includes a lower structure; a first body that is provided in a pivotal manner with respect to the lower structure, the first body opening and closing an upper portion of the lower structure by pivotal movement; a second body that is provided in a pivotal manner with respect to the first body, the second body opening and closing, by pivotal movement, an upper portion of the first body; a first angle restricting section that restricts a maximum opening angle of the second body with respect to the first body to a first angle when the first body is in a closed state; and a second angle restricting section that restricts a maximum opening angle of the second body with respect to the first to a second angle that is smaller than the first angle when the first body is in an open state.

### BACKGROUND

1. Technical Field

The present invention relates to an image reading apparatus, a representative example of which is a scanner.

2. Incorporated by Reference

The entire disclosure of Japanese Patent Application No. 2013-069412, filed Mar. 28, 2013 is expressly incorporated by reference herein.

3. Related Art

As disclosed in JP-A-2007-336273, there are cases in which a scanner, serving as an example of an image reading apparatus, is provided above an upper portion of a recording device, serving as an example of a lower structure, that carries out recording on recording paper. In the above case, the scanner is provided in an openable and closable manner with respect to the upper portion of the recording device to allow maintenance of the recording device to be carried out. The opening and closing of the scanner is typically carried out by pivotal movement of the scanner.

Furthermore, a cover that opens and closes with respect to a document platen is provided on the upper portion of the scanner. The cover typically opens and closes with respect to the document platen by pivotal movement. Alternatively, in place of the above cover, there are cases in which an automatic document transport device called an automatic document feeder (ADF) is provided on the upper portion of the scanner; however, in such cases as well, the automatic document feeder is typically provided so as to open and close with respect to the document platen by pivotal movement.

As described above, in a case in which the scanner body is provided in an openable and closable manner above the upper portion of the recording device (a printer) serving as a lower structure and in which the scanner body is provided in an openable and closable manner with respect to a document cover (alternatively, an automatic document feeder), when the scanner body is opened while the document cover is in an open state, the document cover becomes pivoted even further with respect to the recording device.

For example, in a case in which the scanner body and the document cover are both structured so as to open towards the rear side of the recording device, if the scanner body is opened while the document cover is in an open state, the document cover disadvantageously opens further towards the rear side of the recording device and, thus, a large space will be required at the back of the device. Furthermore, in a case in which the device is installed without sufficient space at its back, when the scanner body is opened while the document cover is in an open state, the document cover may hit an object, such as a wall, at the back of the device and the document cover may become damaged.

### SUMMARY

An advantage of an aspect of the invention is that, while including a plurality of opening and closing bodies on an upper portion of a lower structure, an image reading apparatus is provided that can prevent an opening and closing body positioned on the upper side from becoming widely opened even when an opening and closing body positioned on the lower side is opened.

An image reading apparatus according to an aspect of the invention includes a lower structure; a first opening and closing body that is provided in a pivotal manner with respect to the lower structure, the first opening and closing body opening and closing an upper portion of the lower structure by pivotal movement; a second opening and closing body that is provided in a pivotal manner with respect to the first opening and closing body, the second opening and closing body opening and closing, by pivotal movement, an upper portion of the first opening and closing body in a direction that is the same as a direction in which the first opening and closing body is opened and closed; a first angle restricting section that restricts a maximum opening angle of the second opening and closing body with respect to the first opening and closing body to a first angle when the first opening and closing body is in a closed state; and a second angle restricting section that restricts a maximum opening angle of the second opening and closing body with respect to the first opening and closing body to a second angle that is smaller than the first angle when the first opening and closing body is in an open state.

According to the aspect, when the first opening and closing body is in the closed state, the maximum opening angle of the second opening and closing body with respect to the first opening and closing body is restricted by the first angle restricting section to the first angle, and when the first opening and closing body is in the open state, the maximum opening angle of the second opening and closing body with respect to the first opening and closing body is restricted by the second angle restricting section that is different to the first angle restricting section to the second angle that is smaller than the first angle; accordingly, when the first opening and closing body is opened, the second opening and closing body can be prevented from opening in a wide manner with respect to the lower structure when the first opening and closing body are opened. Accordingly, the installation space of the device can be reduced and, at the same time, the second opening and closing body can be prevented from being damaged or the risk of the second opening and closing body being damaged can be reduced.

In the image reading apparatus according to the aspect, the first angle restricting section is preferably provided in the first opening and closing body.

According to such an image reading apparatus, since the first angle restricting section is preferably provided in the first opening and closing body, the maximum opening angle of the second opening and closing body can be restricted even when the first opening and closing body is in a separated state with the lower structure. For example, the second opening and closing body can be kept at a predetermined angle during the assembly process of the device and work efficiency can be facilitated.

In the image reading apparatus according to the aspect, the second angle restricting section is preferably provided in the lower structure.

According to such an image reading apparatus, since the second angle restricting section is preferably provided in the lower structure, regardless of the state in which the first opening and closing body is in, the maximum opening angle of the second opening and closing body can be restricted reliably.

In the image reading apparatus according to the aspect, when the second opening and closing body is in the open state and when the first opening and closing body is changed from the closed state to the open state, with the pivoting of the first opening and closing body that restricts the opening angle of the second opening and closing body to the first angle, an abutting state of the first angle restricting section and the second opening and closing body is preferably canceled and is preferably changed to an abutting state of the second angle restricting section and the second opening and closing body, the abutting state of the second angle restricting section and the second opening and closing body preferably regulating the opening angle of the second opening and closing body to the second angle.

In the image reading apparatus according to the aspect, the first opening and closing body preferably includes a document platen on which a document is placed, and the second opening and closing body is preferably a cover that opens and closes with respect to the document platen.

The image reading apparatus according to the aspect is configured such that the first opening and closing body preferably includes a document platen on which a document is placed, and the second opening and closing body is preferably a cover that opens and closes with respect to the document platen, accordingly, the advantageous effects of the first aspect described above can be obtained.

In the image reading apparatus according to the aspect, the first opening and closing body preferably includes a document platen on which a document is placed, and the second opening and closing body is preferably a transport device that transports a document to an image reading position on the document platen.

According to such an image reading apparatus, the first opening and closing body preferably includes a document platen on which a document is placed, and the second opening and closing body is preferably a transport device that transports a document to an image reading position on the document plate, accordingly, the advantageous effects of the first aspect described above can be obtained.

In the image reading apparatus according to the aspect, the second opening and closing body can preferably be displaced in a direction in which the second opening and closing body advances and retreats with respect to the document platen.

According to such an image reading apparatus, since the second opening and closing body can preferably be displaced in a direction in which the second opening and closing body advances and retreats with respect to the document platen, when the second opening and closing body is in a closed state, the position of the second opening and closing body with respect to the document platen can be adjusted in accordance with the thickness of the document that is placed on the document platen. Accordingly, the second opening and closing body (cover) can press the overall document placed on the document platen in a uniform manner and a satisfactory reading result can be obtained.

In the image reading apparatus according to the aspect, the lower structure is preferably provided with a recording component that performs recording on a medium.

Since the image reading apparatus according to the aspect is configured such that the lower structure is preferably provided with a recording component that performs recording on a medium, the advantageous effects of the first aspect described above can be obtained.

### BRIEF DESCRIPTION OF THE DRAWINGS

The invention will be described with reference to the accompanying drawings, wherein like numbers reference like elements.

FIG. 1 is a left-side view of a multifunction printer that is an example of the image reading apparatus according to the invention.

FIG. 2 is a left-side view of the multifunction printer that is an example of the image reading apparatus according to the invention.

FIG. 3 is a left-side view of the multifunction printer that is an example of the image reading apparatus according to the invention.

FIG. 4 is an enlarged left side view of a rear portion of the multifunction printer that is an example of the image reading apparatus according to the invention.

FIG. 5 is an enlarged left side view of the rear portion of the multifunction printer that is an example of the image reading apparatus according to the invention.

FIG. 6 is an enlarged left side view of the rear portion of the multifunction printer that is an example of the image reading apparatus according to the invention.

FIG. 7 is an enlarged cross-sectional view of the left rear portion of the multifunction printer that is an example of the image reading apparatus according to the invention.

FIG. 8 is an enlarged cross-sectional view of the rear portion of the multifunction printer that is an example of the image reading apparatus according to the invention.

FIG. 9 is an enlarged cross-sectional view of the rear portion of the multifunction printer that is an example of the image reading apparatus according to the invention.

FIG. 10 is an enlarged cross-sectional view of the rear portion of the multifunction printer that is an example of the image reading apparatus according to the invention.

### DESCRIPTION OF EXEMPLARY EMBODIMENTS

An exemplary embodiment of the invention will be described next with reference to the drawings.

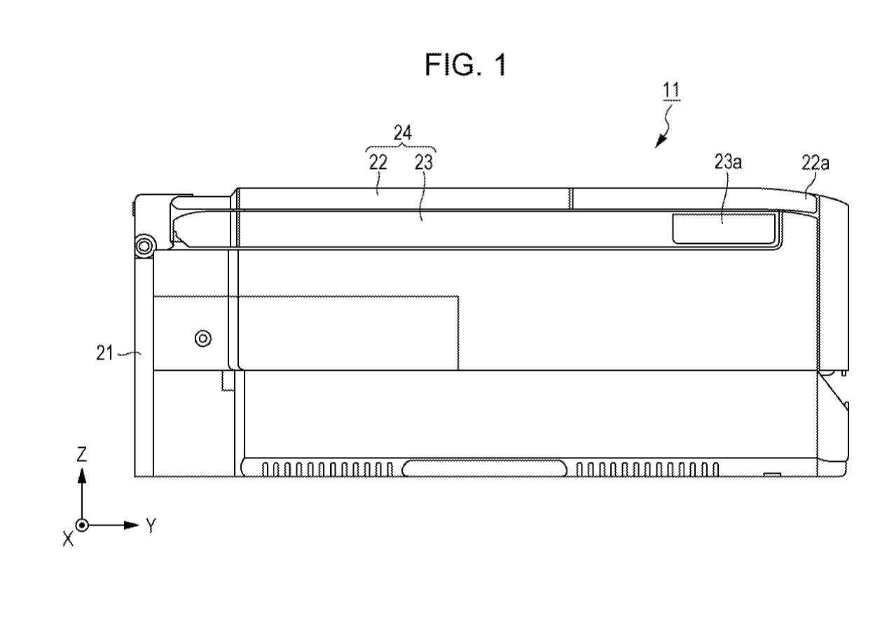

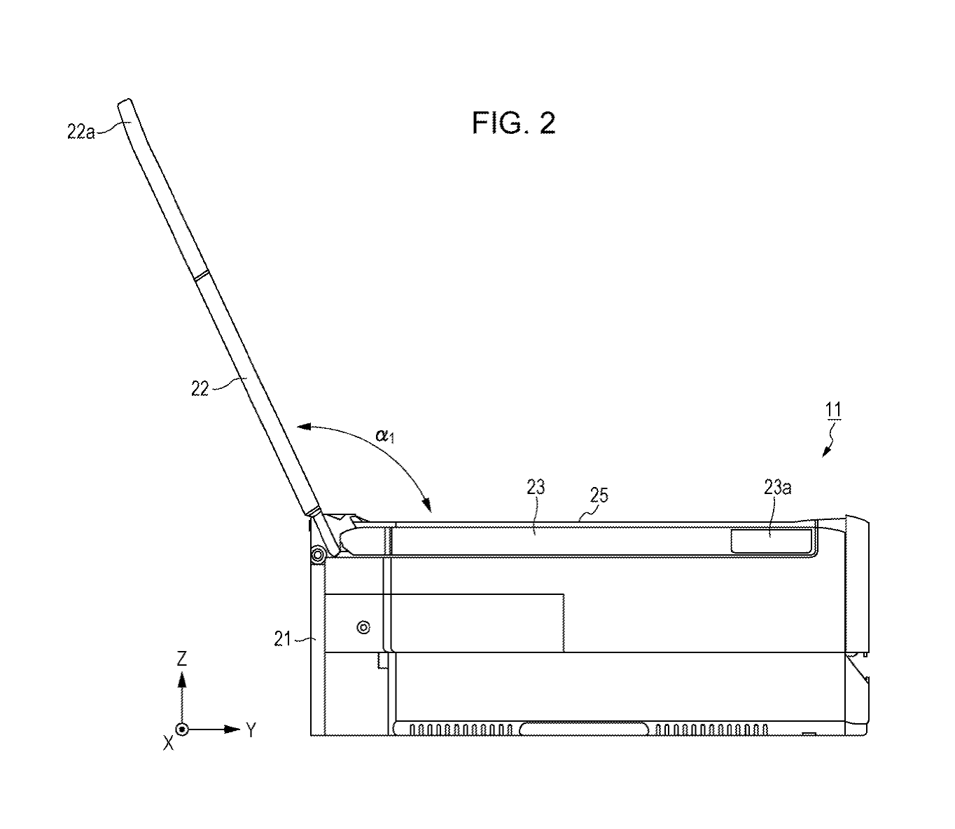

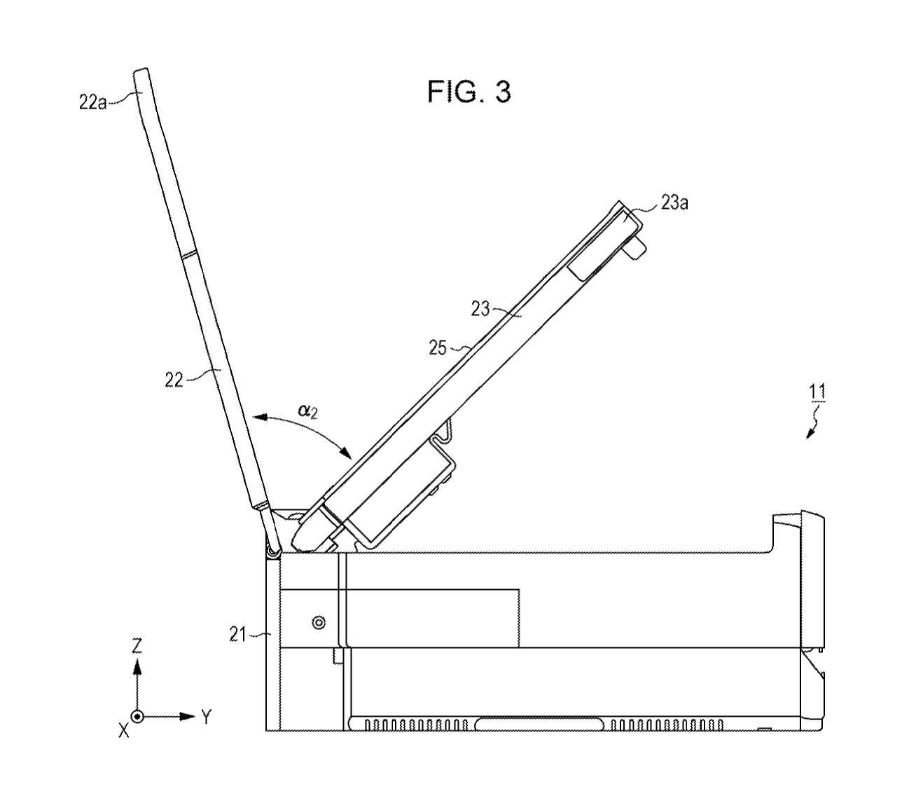

FIGS. 1 to 3 are left-side views each illustrating an appearance of a multifunction printer 11 that is an example of an image reading apparatus according to the invention. FIG. 1 is a left-side view illustrating an appearance of the multifunction printer 11 in which a cover 22 and a scanner body 23 are closed. FIG. 2 is a left-side view illustrating an appearance of the multifunction printer 11 in which the cover 22 has been opened while the scanner body 23 is kept closed. FIG. 3 is a left-side view illustrating an appearance of the multifunction printer 11 in which the cover 22 and the scanner body 23 have been opened.

Note that, hereinafter, a Y-axis corresponds to a front-rear direction of the multifunction printer 11, a Z-axis corresponds to an up-down direction thereof, and an X-axis corresponds to a left-right direction thereof. Furthermore, hereinafter, regarding the X-axis direction, the near side in FIG. 1 is simply referred to as a left side and the far side is simply referred to as a right side. Furthermore, hereinafter, regarding the Y-axis direction, the right side in FIG. 1 is simply referred to as a front side and the left side is simply referred to as a rear side. In addition, hereinafter, regarding the Z-axis direction, the upper side in FIG. 1 is simply referred to as an upper side and the lower side is simply referred to as a lower side.

The multifunction printer 11 is provided with a scanner unit 24 on the upper portion of a printer unit (hereinafter, referred to as “main body”) 21. In other words, the multifunction printer 11 has a recording function of carrying out recording on a sheet that is an example of a medium and has a scanning function of reading a document. The scanner unit 24 includes the cover 22 and the scanner body 23. The main body 21 is an example of a lower structure and includes recording components, which carry out recording on a medium, such as a recording head (not shown) that prints characters and images on a sheet with ink or the like.

The cover 22 is provided in an openable and closable manner with respect to the scanner body 23. The scanner body 23 is provided in an openable and closable manner with respect to the main body 21. Users can open and close the cover 22 with respect to the scanner body 23 and, furthermore, can open and close the scanner body 23 with respect to the main body 21. When the cover 22 is opened, a document platen 25 comes into sight. Furthermore, when the scanner body 23 is opened, the interior of the main body 21 comes into sight and operations such as ink cartridge replacement and a process performed when paper is jammed can be carried out. Note that the term “users” not only refers to end users but also refers to anyone who handles the multifunction printer 11 such as those who carry out assembly work and those who carry out customer service for the multifunction printer 11.

The cover 22 is an example of a second opening and closing body, and by closing the cover 22 with respect to the document platen 25, the document platen 25 provided in the upper surface of the scanner body 23 can be covered, and by opening the cover 22 with respect to the document platen 25, a document can be placed on the upper side of the document platen 25.

The scanner body 23 is an example of a first opening and closing body and reads an image that is recorded on a document that is placed on the document platen 25 that is provided on the upper surface of the scanner body 23. In other words, the scanner body 23 includes the document platen 25, on which a document is placed, and the cover 22 is a cover that opens and closes with respect to the document platen 25.

When the user lifts up a front end 22a of the cover 22 that is in a closed state, the cover 22 is pivoted in a counterclockwise direction in FIGS. 1 and 2 about a shaft (described later) that is provided at a rear end of the cover 22. Accordingly, as illustrated in FIG. 2, the cover 22 is opened at angle α₁ with respect to the scanner body 23. Conversely, when the user lowers the front end 22a of the cover 22 that is in an open state, the cover 22 is pivoted in a clockwise direction in FIGS. 1 and 2 about the shaft (described later) that is provided at the rear end of the cover 22. Accordingly, the cover 22 is closed with respect to the scanner body 23.

As described above, the cover 22 is provided in a pivotal manner with respect to the scanner body 23. By pivoting the cover 22, the upper portion of the scanner body 23 is opened and closed.

When the user lifts up a front end 23a of the scanner body 23 that is in a closed state while the cover 22 is in the open state, the scanner body 23 is pivoted in a counterclockwise direction in FIGS. 2 and 3 about a shaft (described later) that is provided at the rear end of the scanner body 23. Accordingly, as illustrated in FIG. 3, the scanner body 23 is opened with respect to the main body 21 in the same direction as that in which the cover 22 opens. At this time, as illustrated in FIG. 3, the cover 22 is opened at angle α₂ with respect to the scanner body 23. Note that angle α₂ is smaller than angle α₁.

When the user lowers the front end 23a of the scanner body 23 while the cover 22 and the scanner body 23 are in the open state, the scanner body 23 is pivoted in a clockwise direction in FIGS. 2 and 3 about the shaft (described later) that is provided at the rear end of the scanner body 23. Accordingly, the scanner body 23 is closed with respect to the main body 21.

As described above, the scanner body 23 is provided in a pivotal manner with respect to the main body 21, and by pivoting the scanner body 23, the upper portion of the main body 21 is opened and closed. The opening and closing direction of the cover 22 and the opening and closing direction of the scanner body 23 are the same.

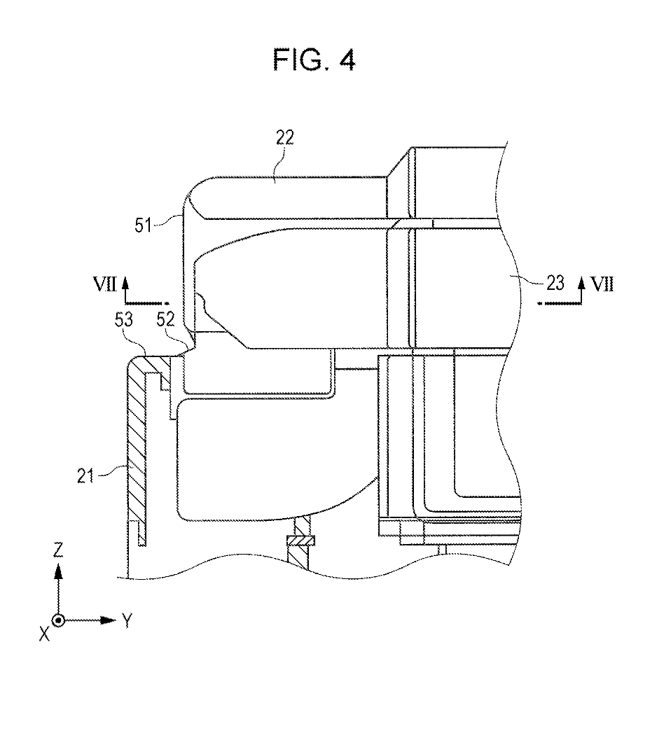

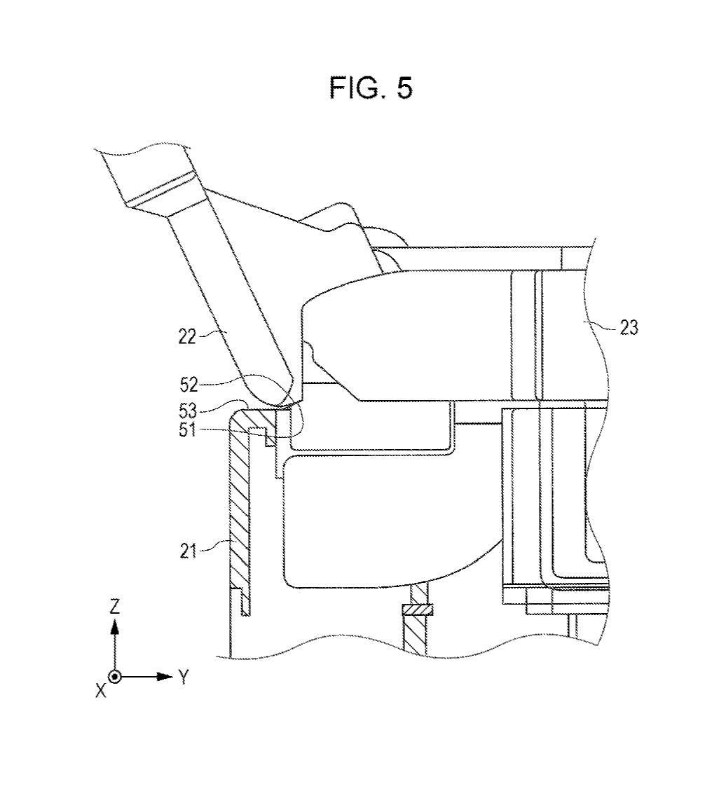

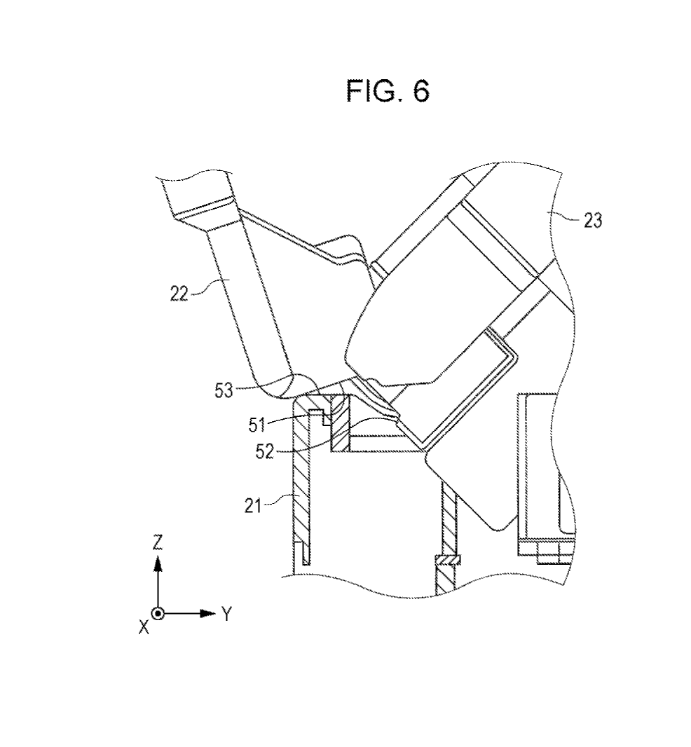

Regulation of the opening angle of the cover 22 will be described next with reference to FIGS. 4 to 10. FIG. 4 is an enlarged left-side view that is an enlarged view of the lateral side of the rear portion of the multifunction printer 11 in which the cover 22 and the scanner body 23 are in the closed state. FIG. 5 is an enlarged left-side view that is an enlarged view of the lateral side of the rear portion of the multifunction printer 11 in which the cover 22 is in the open state while the scanner body 23 is kept closed. FIG. 6 is an enlarged left-side view that is an enlarged view of the lateral side of the rear portion of the multifunction printer 11 in which the cover 22 and the scanner body 23 are in the open state.

A working face 51 is formed at the rear end of the cover 22. More specifically, the working face 51 is formed as a face that is parallel to a flat plane defined by the Z-axis and the X-axis when the cover 22 is in the closed state. A cover receiving face 52 is formed at the rear end of the scanner body 23. More specifically, the cover receiving face 52 is formed at a position that comes into contact with the working face 51 of the opened cover 22 when the cover 22 is opened while the scanner body 23 is kept closed. The cover receiving face 52 is a face formed of a flat face that is parallel to a flat plane defined by the Y-axis and the X-axis, in other words, a flat face that is parallel to a horizontal plane, and a curved face that extends downwards continuously from the rear side of the flat face as it extends to the rear side.

A cover receiving face 53 is formed on the upper surface of the rear end of the main body 21. More specifically, the cover receiving face 53 is formed at a position that comes into contact with the working face 51 of the opened cover 22 when the cover 22 and the scanner body 23 are opened. The cover receiving face 53 is formed as a face that is parallel to a flat plane that is defined by the Y-axis and the X-axis, in other words, a flat plane that is parallel to a horizontal plane.

When the cover 22 and the scanner body 23 are in the closed state, as illustrated in FIG. 4, the working face 51 is generally a vertical face and the cover receiving face 52 and the cover receiving face 53 are generally horizontal faces. As is clear from FIG. 4, when in the above state, the working face 51, the cover receiving face 52, and the cover receiving face 53 are not in contact with each other; accordingly, the positions of the cover 22 and the scanner body 23 are not restricted by the working face 51, the cover receiving face 52, and the cover receiving face 53.

When the cover 22 is opened to its maximum opening angle while the scanner body 23 is kept in the closed state, as illustrated in FIG. 5, the working face 51 comes into contact with the cover receiving face 52. The working face 51 and the cover receiving face 52 come into contact with each other; accordingly, the angle of the cover 22 with respect to the scanner body 23 becomes restricted. In other words, the cover receiving face 52 restricts the maximum opening angle of the cover 22 with respect to the scanner body 23 to angle α₁ when the scanner body 23 is in the closed state.

Furthermore, when the scanner body 23 is opened with respect to the main body 21 while the cover 22 is kept open at its maximum opening angle, as illustrated in FIG. 6, the cover 22 is displaced to the rear side in accordance with the opening of the scanner body 23, and the working face 51 becomes abutted against the cover receiving face 53. The working face 51 and the cover receiving face 53 come into contact with each other; accordingly, the angle of the cover 22 with respect to the scanner body 23 is restricted. In other words, when the scanner body 23 is in the open state, the cover receiving face 53 restricts the maximum opening angle of the cover 22 with respect to the scanner body 23 to angle α₂ that is smaller than angle α₁.

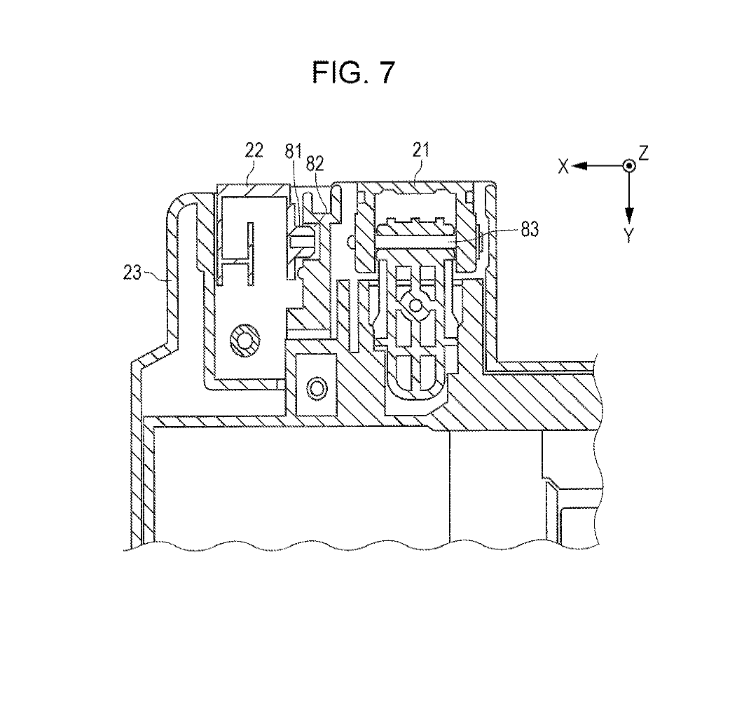

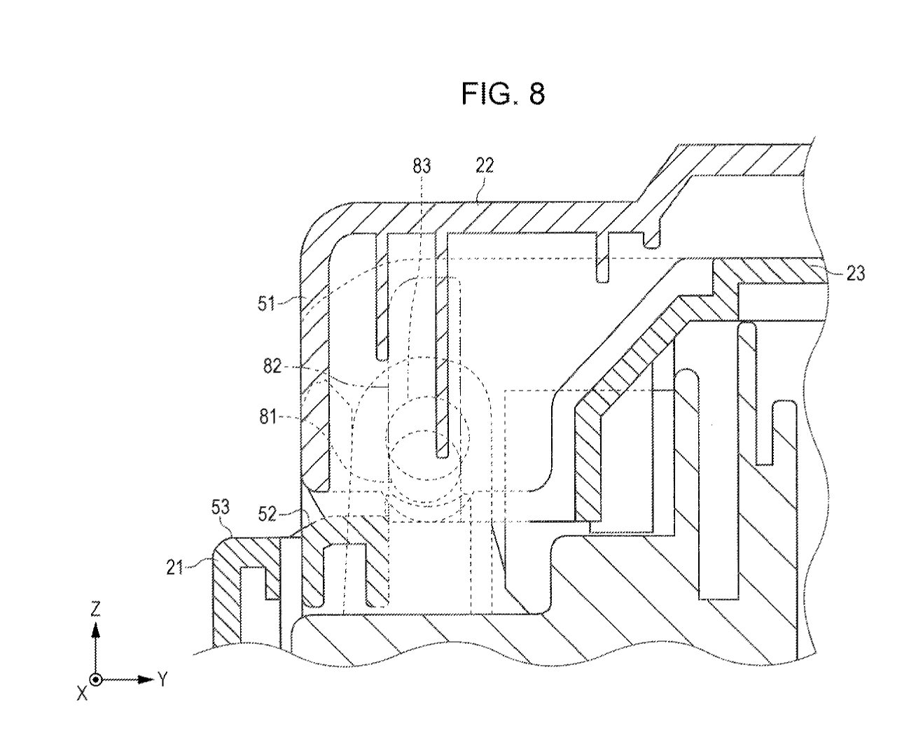

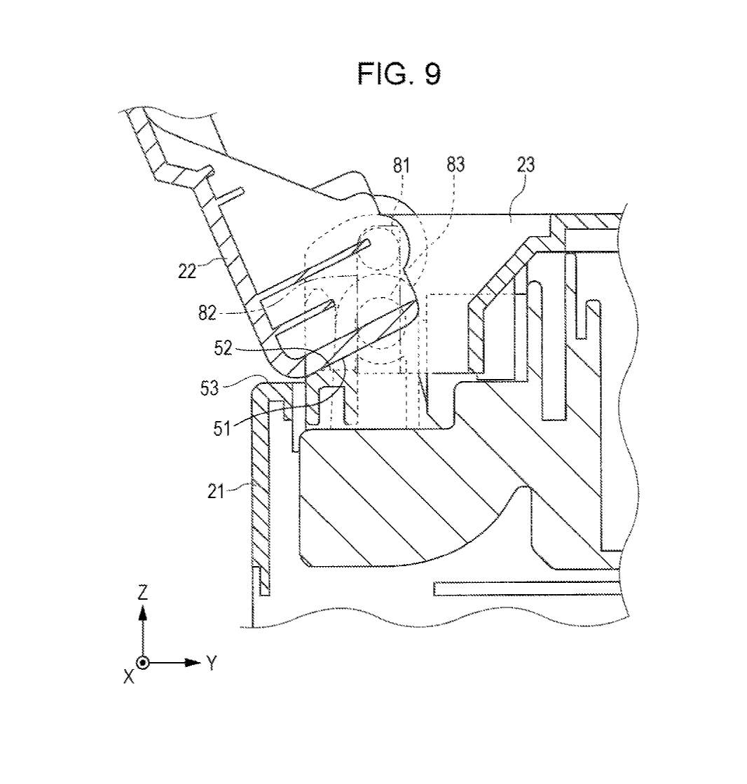

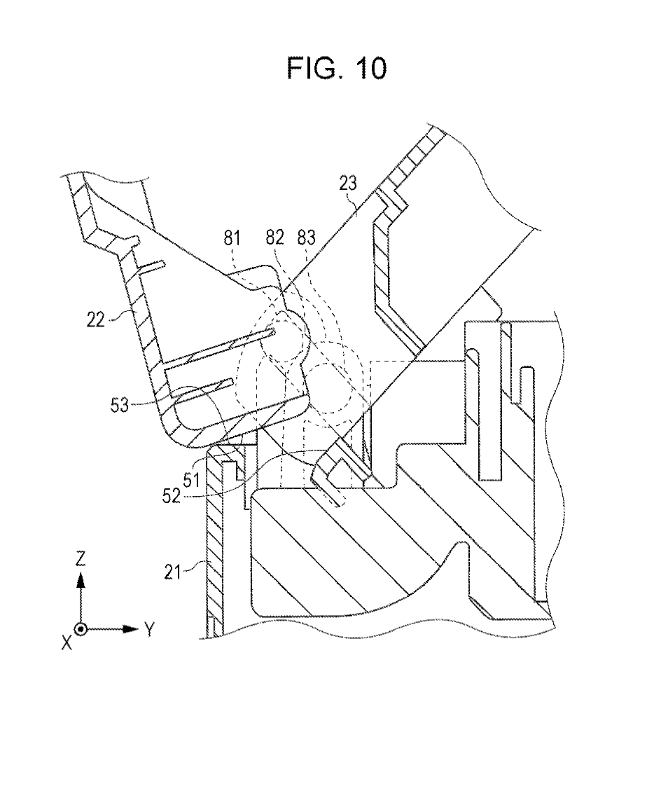

FIG. 7 is an enlarged cross-sectional view of the multifunction printer 11, which is an enlarged view of a section taken along the line VII-VII of FIG. 4. FIG. 8 is a sectional side view of the rear portion of the multifunction printer 11 when the cover 22 and the scanner body 23 are in a closed state. FIG. 9 is a sectional side view of the rear portion of the multifunction printer 11 when the cover 22 is in the open state while the scanner body 23 is kept closed. FIG. 10 is a sectional side view of the rear portion of the multifunction printer 11 when the cover 22 and the scanner body 23 are in the open state. Note that, in FIGS. 8 to 10, in order to depict the components from the X-axis direction in a single drawing and in order to avoid making the drawings complicated, the components are illustrated by using solid lines, broken lines, and phantom lines; however, the positional relationship between the components in the X-axis direction is not depicted in an exact manner and the positional relationship between the components in the X-axis direction corresponds to that illustrated in FIG. 7.

A cover rotating shaft 81 that is a cylindrical protrusion is formed in the cover 22. A scanner groove 82 that is a long groove extending in the Z-axis direction and that is a groove that has a shape allowing the cover rotating shaft 81 to be inserted therein is formed in the scanner body 23. When the cover rotating shaft 81 is inserted into the scanner groove 82, the cover 22 is held by the scanner body 23 in a pivotal manner. The cover rotating shaft 81 can move inside the scanner groove 82; accordingly, the cover 22 can be displaced in the direction in which the scanner body 23 advances and retreats with respect to the document platen 25.

A scanner rotating shaft 83 is provided in the scanner body 23. The scanner rotating shaft 83 is supported by the main body 21 in a pivotal manner; accordingly, the scanner body 23 is held by the main body 21 in a pivotal manner. Note that unlike the cover rotating shaft 81, the scanner rotating shaft 83 cannot move in the Z-axis direction.

As illustrated in FIGS. 7 and 8, the position of the scanner groove 82 and that of the scanner rotating shaft 83 in the Y-axis direction are generally the same. When the cover 22 and the scanner body 23 are in a closed state, the cover rotating shaft 81 is positioned lower than the scanner rotating shaft 83.

As illustrated in FIG. 9, when the cover 22 is opened while the scanner body 23 is kept closed, the working face 51 becomes abutted against the cover receiving face 52 and the cover rotating shaft 81 is displaced upwards with respect to the scanner body 23 while the working face 51 is supported by the cover receiving face 52. After the cover rotating shaft 81 has reached the upper end of the scanner groove 82 and while the working face 51 is supported by the cover receiving face 52, the cover 22 is opened at angle α₁ with respect to the scanner body 23. The cover receiving face 52 restricts the angle of the cover 22 with respect to the scanner body 23. At this time, since the cover rotating shaft 81 has reached the upper end of the scanner groove 82, the cover rotating shaft 81 is positioned above the scanner rotating shaft 83.

When the scanner body 23 is opened with respect to the main body 21 while the cover 22 is in the open state, as illustrated in FIG. 10, the cover rotating shaft 81 is positioned above the scanner rotating shaft 83; accordingly, when the scanner body 23 is opened, the cover 22 is displaced to the rear side. Consequently, the working face 51 moves away from the cover receiving face 52 and becomes abutted against the cover receiving face 53. In other words, after the cover rotating shaft 81 reaches the upper end of the scanner groove 82 while the working face 51 is supported by the cover receiving face 53, the cover 22 is opened at angle α₂ with respect to the scanner body 23. The cover receiving face 53 restricts the angle of the cover 22 with respect to the scanner body 23.

Note that, because the scanner groove 82 is a long groove that extends in the Z-axis direction, when a document is set and the cover 22 is closed, the cover 22 can be displaced upwards with respect to the scanner body 23. For example, in a case in which the subject, whose image is to be read, is a thick book, when the cover 22 is closed after the book in its open state has been placed on the document platen 25, which is the upper surface of the scanner body 23, the cover 22 can be closed in a parallel manner with respect to the scanner body 23 since the cover 22 moves upwards. In other words, when the cover 22 is in a closed state, the position of the cover 22 with respect to the document platen 25 can be adjusted in accordance with the thickness of the document that is placed on the document platen 25. Accordingly, the cover 22 can press the overall document placed on the document platen 25 in a uniform manner and a satisfactory reading result can be obtained.

As described above, the multifunction printer 11 includes the main body (apparatus body) 21, the scanner body (first opening and closing body) 23 that is provided in a pivotal manner with respect to the main body 21 and that opens and closes the upper portion of the main body 21 by pivoting, the cover (second opening and closing body) 22 that is provided in a pivotal manner with respect to the scanner body 23 and that opens and closes the upper portion of the scanner body 23 in the same direction as the opening and closing direction of the scanner body 23 by pivoting, the cover receiving face (first angle restricting section) 52 that restricts the maximum opening angle of the cover 22 with respect to the scanner body 23 to angle α₁ when the scanner body 23 is in a closed state, the cover receiving face (second angle restricting section) 53 that restricts the maximum opening angle of the cover 22 with respect to the scanner body 23 to an angle α₂ that is smaller than the angle α₁ when the scanner body 23 is in an open state.

When the scanner body 23 is in the closed state, the cover receiving face 52 restricts the maximum opening angle of the cover 22 with respect to the scanner body 23 to angle α₁, and when the scanner body 23 is in the open state, the cover receiving face 53 that is a face different from the cover receiving face 52 restricts the maximum opening angle of the cover 22 with respect to the scanner body 23 to angle α₂ that is smaller than angle α₁; accordingly, when the scanner body 23 is opened, the cover 22 can be prevented from further opening with respect to the main body 21. Accordingly, the installation space of the device can be reduced and, at the same time, the cover 22 can be prevented from being damaged or the risk of the cover 22 being damaged can be reduced.

Since the cover receiving face 52 is provided in the scanner body 23 rather than in the main body 21, the maximum opening angle of the cover 22 can be restricted even when the scanner body 23 is separated from the main body 21. For example, the cover 22 can be kept at a predetermined angle during the assembly process of the device and work efficiency can be facilitated.

Furthermore, since the cover receiving face 53 is provided on the main body 21, regardless of the state in which the scanner body 23 is in, the maximum opening angle of the cover 22 can be restricted reliably.

Note that when the cover (second opening and closing body) 22 is in the open state and when the scanner body (first opening and closing body) 23 is changed from its closed state to its open state, with the pivoting of the scanner body 23 that restricts the opening angle of the cover 22 to a first angle (angle α₁), the abutting state of the cover receiving face 52 (first angle restricting section) and the cover 22 is canceled and is changed to the abutting state of the cover receiving face 53 (second angle restricting section) and the cover 22, which restricts the opening angle of the cover 22 to a second angle (angle α₂).

Furthermore, since the cover 22 can be displaced in the direction in which the cover 22 advances and retreats with respect to the document platen 25, when the cover 22 is in a closed state, the position of the cover 22 with respect to the document platen 25 can be adjusted in accordance with the thickness of the document placed on the document platen 25. Accordingly, the cover 22 can press the overall document placed on the document platen 25 in a uniform manner and a satisfactory reading result can be obtained.

Note that the invention is not limited to the exemplary embodiment described above and may be modified in various ways that is within the scope of the claims. It goes without saying that the modifications are also included in the scope of the invention.

For example, in the present exemplary embodiment, the first opening and closing body is a scanner body 23 and the second opening and closing body is a cover 22; however, the relation may be the other way round and the first opening and closing body may be a cover 22 and the second opening and closing body may be a scanner body 23.

Furthermore, in the present exemplary embodiment, the cover 22 serving as the second opening and closing body has been described as a cover that covers the document platen 25 of the scanner body 23 or that is opened with respect to the document platen 25 of the scanner body 23; however, the cover 22 may alternatively be an automatic document feeding device that is typically called an automatic document feeder (ADF) that automatically transports the document to the reading position or may be other types of opening and closing bodies.

In addition, in the present exemplary embodiment, the first opening and closing body is a scanner body 23; however, not limited to a scanner body 23, the first opening and closing body may be any component that opens and closes the upper portion of the lower structure (the main body 21 in the present exemplary embodiment).

Furthermore, the lower structure (the main body 21 in the present exemplary embodiment) is not limited to a recording device and the lower structure may have any kind of function. For example, the lower structure may be provided with a scanning function and the first opening and closing body may be an opening and closing body that opens and closes with respect to the document platen.

Still Further, the lower structure may be a recording device and the first and second opening and closing bodies may be opening and closing bodies other than a scanner. In other words, the device including the lower structure and the first and second opening and closing bodies may be a recording device that carries out recording on a medium. Additionally, in the above described exemplary embodiment, the lower structure is a recording device, the first opening and closing body is a scanner, and the second opening and closing body is a cover, and the entire device configured with these components is referred to as an image reading apparatus; however, it may be alternatively called a recording device.

What is claimed is:

1. An image reading apparatus that reads an image, the image reading apparatus comprising:
a lower structure;
a first opening and closing body that is provided in a pivotal manner with respect to the lower structure, the first opening and closing body opening and closing an upper portion of the lower structure by pivotal movement;
a second opening and closing body that is provided in a pivotal manner with respect to the first opening and closing body, the second opening and closing body opening and closing, by pivotal movement, an upper portion of the first opening and closing body in a direction that is the same as a direction in which the first opening and closing body is opened and closed;
a first angle restricting section that restricts a maximum opening angle of the second opening and closing body with respect to the first opening and closing body to a first angle when the first opening and closing body is in a closed state; and
a second angle restricting section that restricts a maximum opening angle of the second opening and closing body with respect to the first opening and closing body to a second angle that is smaller than the first angle when the first opening and closing body is in an open state.

2. The image reading apparatus according to claim 1, wherein
the first angle restricting section is provided in the first opening and closing body.

3. The image reading apparatus according to claim 1, wherein
the second angle restricting section is provided in the lower structure.

4. The image reading apparatus according to claim 1, wherein
when the second opening and closing body is in the open state and when the first opening and closing body is changed from the closed state to the open state, with the pivoting of the first opening and closing body that restricts the opening angle of the second opening and closing body to the first angle, an abutting state of the first angle restricting section and the second opening and closing body is canceled and is changed to an abutting state of the second angle restricting section and the second opening and closing body, the abutting state of the second angle restricting section and the second opening and closing body regulating the opening angle of the second opening and closing body to the second angle.

5. The image reading apparatus according to claim 1, wherein
the first opening and closing body includes a document platen on which a document is placed, and
the second opening and closing body is a cover that opens and closes with respect to the document platen.

6. The image reading apparatus according to claim 1, wherein
the first opening and closing body includes a document platen on which a document is placed, and
the second opening and closing body is a transport device that transports a document to an image reading position on the document platen.

7. The image reading apparatus according to claim 5, wherein
the second opening and closing body can be displaced in a direction in which the second opening and closing body advances and retreats with respect to the document platen.

8. The image reading apparatus according to claim 1, wherein
the lower structure is provided with a recording component that performs recording on a medium.
